(19) United States
(12) Patent Application Publication
(10) Pub. No.: US 2025/0328054 A1
(43) Pub. Date: Oct. 23, 2025

(54) OPTICAL MODULE

(71) Applicant: FURUKAWA ELECTRIC CO., LTD., Tokyo (JP)

(72) Inventors: Kazuya NAGASHIMA, Tokyo (JP); Atsushi IZAWA, Tokyo (JP); Atsushi KAJI, Tokyo (JP); Noritaka MATSUBARA, Tokyo (JP); Yozo ISHIKAWA, Tokyo (JP)

(73) Assignee: FURUKAWA ELECTRIC CO., LTD., Tokyo (JP)

(21) Appl. No.: 19/255,151

(22) Filed: Jun. 30, 2025

Related U.S. Application Data
(63) Continuation of application No. PCT/JP2024/001688, filed on Jan. 22, 2024.

(30) Foreign Application Priority Data
Jan. 20, 2023 (JP) 2023-007484

(51) Int. Cl. G02F 1/21

(52) U.S. Cl. CPC G02F 1/21

(57) ABSTRACT

An optical module includes: a housing; a light emitting device housed in the housing; a wavelength detecting unit configured to detect wavelength of a first light which is output in a first direction from the light emitting device housed in the housing; and an optical device housed in the housing and configured to receive input of a second light traveling substantially parallel to the first light. A first incident surface of the wavelength detecting unit, on which the first light falls, is positioned away from a second incident surface of the optical device, on which the second light falls, in an opposite direction of the first direction.

This application is a continuation of International Application No. PCT/JP2024/001688, filed on Jan. 22, 2024 which claims the benefit of priority of the prior Japanese Patent Application No. 2023-007484, filed on Jan. 20, 2023, the entire contents of which are incorporated herein by reference.

### BACKGROUND

The present disclosure relates to an optical module.

In the related art, an optical module is known that includes a light emitting device, a wavelength detecting unit, and an optical device; and optical transmission occurs inside the housing of the optical module (for example, refer to International Laid-open Pamphlet No. 2020/138337). The light emitting device is, for example, a laser device. The wavelength detecting unit is, for example, a wavelength locker. The optical device is, for example, a coherent mixer or a modulator.

### SUMMARY

In an optical module of such a type, the situation in which the stray light that is generated due to the reflection or the scattering occurring in the optical device falls onto the wavelength detecting unit is not a desirable situation due to the risk of a decline in the detection accuracy of the wavelength.

There is a need for an optical module that has a new and improved configuration and that enables holding down the impact of the stray light on the wavelength detecting unit.

According to one aspect of the present disclosure, there is provided an optical module including: a housing; a light emitting device housed in the housing; a wavelength detecting unit configured to detect wavelength of a first light which is output in a first direction from the light emitting device housed in the housing; and an optical device housed in the housing and configured to receive input of a second light traveling substantially parallel to the first light, wherein a first incident surface of the wavelength detecting unit, on which the first light falls, is positioned away from a second incident surface of the optical device, on which the second light falls, in an opposite direction of the first direction.

### BRIEF DESCRIPTION OF THE DRAWINGS

FIG. 1 is an exemplary and schematic planar view of an optical module according to a first embodiment;

FIG. 2 is an exemplary and schematic planar view of an optical module according to a second embodiment;

FIG. 3 is an exemplary and schematic planar view of the internal structure of an optical module according to a third embodiment;

FIG. 4 is an exemplary and schematic planar view of the internal structure of an optical module according to a fourth embodiment;

FIG. 5 is an exemplary and schematic planar view of the internal structure of an optical module according to a fifth embodiment;

FIG. 6 is an exemplary and schematic front view of some portion of the internal structure of the optical module according to the fifth embodiment;

FIG. 7 is an exemplary and schematic planar view of the internal structure of an optical module according to a sixth embodiment; and

FIG. 8 is an exemplary and schematic front view of some portion of the internal structure of the optical module according to the sixth embodiment.

### DETAILED DESCRIPTION

Exemplary embodiments of the present disclosure are described below. The configurations explained in the embodiments described below as well as the actions and the results (effects) attributed to the configurations are only exemplary. Thus, the present disclosure may be implemented also using some different configuration than the configurations disclosed in the embodiments described below. Meanwhile, according to the present disclosure, it becomes possible to achieve at least one of various effects (including secondary effects) that are attributed to the configurations.

The embodiments described below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In this specification, ordinal numbers are assigned only for convenience and with the aim of differentiating among the members, the parts, the lights, and the directions. Thus, the ordinal numbers do not indicate the priority or the sequencing.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other.

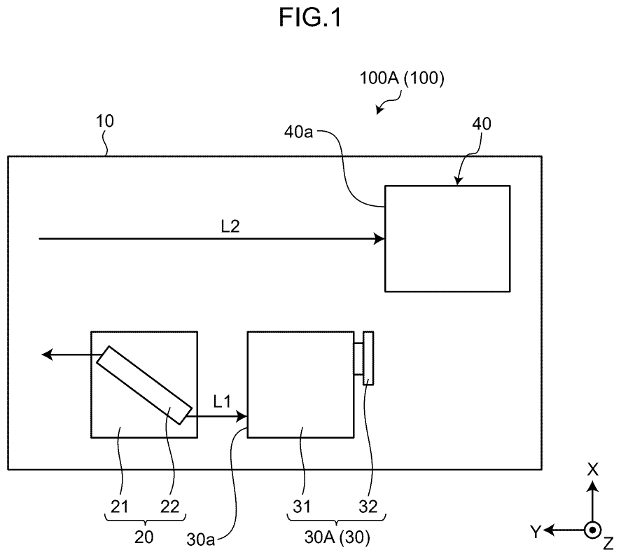

FIG. 1 is a planar view of an optical module 100A (100) according to a first embodiment. As illustrated in FIG. 1, the optical module 100A (100) includes a housing 10, a chip-on-submount 20, a wavelength detecting unit 30A (30), and an optical device 40.

The housing 10 is configured to have a box-shape; and is used to house the chip-on-submount 20, the wavelength detecting unit 30A, the optical device 40, and a temperature regulation device (not illustrated). The housing 10 has a bottom wall, a peripheral wall (side wall), and a top wall (not illustrated). The bottom wall that supports the housed contents may be made of a material having high thermal conductivity, such as copper tungsten (CuW), copper molybdenum (CuMo), or aluminum oxide (Al₂O₃). The peripheral wall and the top wall may be made of a material having a low thermal expansion coefficient, such as an Fe—Ni—Co alloy or aluminum oxide (Al₂O₃).

The chip-on-submount 20 includes, for example, a submount 21 and a laser device 22 that is disposed on the submount 21. The laser device 22 is, for example, a semiconductor laser device that outputs the principal output light in the Y direction, and outputs a laser light L1 as the output light for wavelength monitoring in the opposite direction of the Y direction. The laser device 22 represents an example of a light emitting device, and the opposite direction of the Y direction represents an example of a first direction. In other words, the Y direction represents an example of the opposite direction of the first direction. The laser light L1 represents an example of a first light.

The wavelength detecting unit 30A (30) includes a first portion that has a waveguide structure including an optical filter, and includes a second portion 32 that includes an intensity detecting unit for detecting the intensity of the light which has passed through a first portion 31. The optical filter included in the first portion 31 is a wavelength filter having a different transmittance according to the wavelength; and its wavelength-transmittance property is set in such a way that, for example, the transmittance of the light becomes the highest at the central wavelength and that the transmittance gradually decreases as the distance from the central wavelength increases. Thus, according to the light-reception intensity of the light that has passed through the first portion 31, the intensity detecting unit included in the second portion 32 may detect the wavelength of the light that has passed through the first portion 31, that is, may detect the wavelength of the light output from the laser device 22. In that case, the first portion 31 may include a plurality of optical filters having different central wavelengths, or may include a reference waveguide not including any optical filter. Moreover, the second portion 32 may include a plurality of intensity detecting units, and each intensity detecting unit may detect the intensity of the light that has passed through the corresponding optical filter, or may detect the intensity of the light of the waveguide not including any optical filter. Each optical filter may be configured as, for example, a ring resonator or a Mach-Zehnder interferometer. Each intensity detecting unit may be configured as, for example, a photodiode. The laser light L1 traveling in the opposite direction of the Y direction falls on an incident surface 30a of the wavelength detecting unit 30. The incident surface 30a represents an example of a first incident surface.

For example, the optical device 40 either is a known coherent mixer as disclosed in International Laid-open Pamphlet No. 2020/138337, or is a modulator. A coherent mixer causes interference between an input laser light L2 and the input signal light (not illustrated), and generates a processing signal light (not illustrated). From the processing signal light, the I and Q components of the X-polarization are obtained, and the I and Q components of the Y-polarization are obtained. On the other hand, a modulator modulates the laser light L2 and generates a modulated light. For example, a modulator is a known phase modulator of the Mach-Zehnder type in which an InP is used as the constituent material, and which is driven by a modulator driver (not illustrated) and which functions as an IQ modulator. Such a phase modulator is identical to, for example, the phase modulator disclosed in International Laid-open Pamphlet No. 2016/021163. The laser light L2 traveling in the opposite direction of the Y direction falls on an incident surface 40a of the optical device 40. The laser light L2 travels substantially parallel to the laser light L1. The incident surface 40a represents an example of a second incident surface. The laser light L2 represents an example of a second light.

As illustrated in FIG. 1, according to the first embodiment, the incident surface 30a is positioned away from the incident surface 40a in the Y direction. In that case, even when the scattering of the laser light L2 at the incident surface 40a causes generation of the stray light, the stray light does not easily reach the incident surface 30a of the wavelength detecting unit 30 because of the fact that the incident surface 30a is positioned away from the incident surface 40a in the Y direction and is positioned behind the first portion 31 with respect to the incident surface 40a.

That is, according to the first embodiment, for example, it becomes possible to obtain the optical module 100A (100) that has a new and improved configuration and that enables holding down the impact of the stray light on the wavelength detecting unit 30.

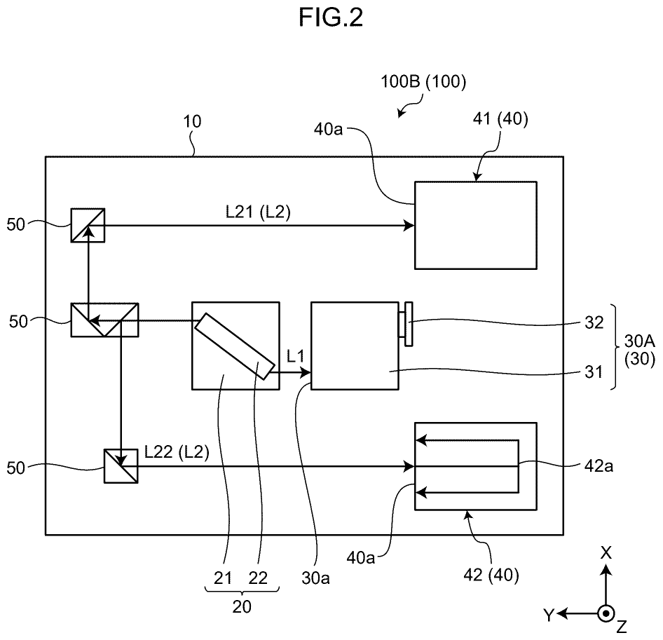

FIG. 2 is a planar view of an optical module 100B (100) according to a second embodiment. As illustrated in FIG. 2, the optical module 100B (100) includes the wavelength detecting unit 30A (30); a coherent mixer 41 and a modulator 42 serving as the optical devices 40; and a plurality of optical components 50. The optical module 100B (100) has an identical configuration to the optical module disclosed in International Laid-open Pamphlet No. 2020/138337.

Each optical component 50 is, for example, a mirror or a beam splitter that branches the laser light, which is output from the laser device 22 in the Y direction, into laser lights L21 and L22 (L2) and returns the laser lights L21 and L22 toward the opposite direction of the Y direction. That is, the laser lights L21 and L22 travel in the opposite direction of the Y direction, travel parallel to each other, and travel parallel to the laser light L1. The laser light L21 (L2) is input to the coherent mixer 41, and the laser light L22 (L2) is input to the modulator 42. With such a configuration, according to the second embodiment, the laser light L1 that is output from the laser device 22 in the Y direction passes through a plurality of optical components 50 and is input as the laser light L2 to each optical device 40. The optical components 50 represent examples of a first optical component. The laser lights L21 and L22 (L2) represent examples of a second light.

In the second embodiment too, in an identical manner to the first embodiment, the incident surface 30a of the wavelength detecting unit 30 is positioned away from the incident surface 40a of the coherent mixer 41 and the incident surface 40a of the modulator 42 in the Y direction.

Thus, in the second embodiment too, in an identical manner to the first embodiment, it becomes possible to obtain the optical module 100B (100) that has a new and improved configuration and that enables holding down the impact of the stray light, which is generated at the incident surface 40a, on the wavelength detecting unit 30.

Moreover, the modulator 42 internally includes a folded waveguide because of which the light travelling in the opposite direction of the Y direction turns around and travels in the Y direction. Moreover, the incident surface 30a of the wavelength detecting unit 30 is positioned away in the Y direction also with respect to a folded portion 42a in the folded waveguide, that is, with respect to the end portion of the folded waveguide in the opposite direction of the Y direction. Furthermore, the wavelength detecting unit 30 is not aligned with the folded portion 42a in the X direction, but is shifted in the Y direction with respect to the position that is aligned with the folded portion 42a in the X direction. Hence, even when the light leaking from the folded portion 42a behaves as the stray light, it does not easily reach the incident surface 30a because of the fact that the incident surface 30a is positioned away from the folded portion 42a in the Y direction and is positioned behind the first portion 31 with respect to the folded portion 42a. Moreover, when the stray light is output in the X direction or in the opposite direction of the X direction, the stray light does not directly reach the wavelength detecting unit 30.

Thus, according to the second embodiment, for example, it becomes possible to obtain the optical module 100B (100) that has a new and improved configuration and that enables holding down the impact of the stray light, which is generated in the folded portion 42a, on the wavelength detecting unit 30.

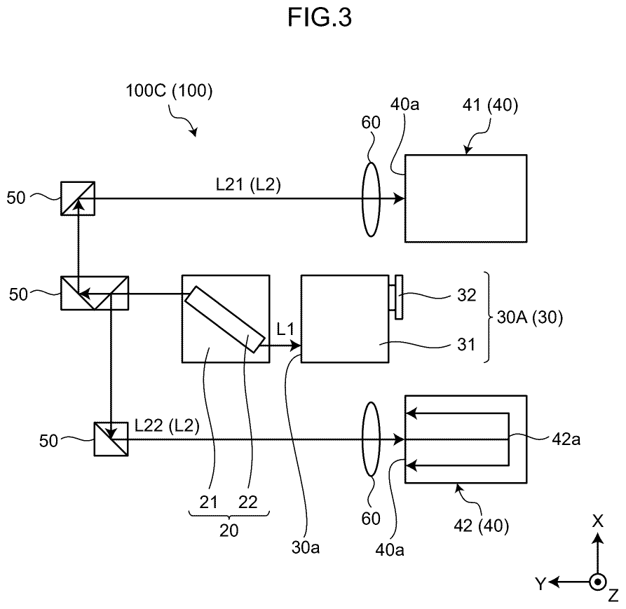

FIG. 3 is a planar view of an optical module 100C (100) according to a third embodiment. In FIG. 3, the housing 10 is not illustrated.

As illustrated in FIG. 3, the optical module 100C (100) according to the third embodiment has an identical configuration to the configuration according to the second embodiment. Hence, according to the third embodiment too, it is possible to achieve identical effects to the effects achieved according to the second embodiment.

However, as illustrated in FIG. 3, the optical module 100C (100) includes lenses 60 through which the laser lights L21 and L22 pass before falling on the incident surface 40a. Each lens 60 faces the incident surface 40a with a gap maintained in the Y direction. The lenses 60 represent examples of a second optical component. However, the second optical component is not limited to the lens 60.

The incident surface 30a of the wavelength detecting unit 30 is positioned away from the lenses 60 in the Y direction. Hence, even if the light scattering at the lenses 60 behave as the stray light, it does not easily reach the incident surface 30a because of the fact that the incident surface 30a is positioned away from the lenses 60 in the Y direction and is positioned behind the first portion 31 with respect to the lenses 60.

Thus, according to the third embodiment, for example, it becomes possible to obtain the optical module 100C (100) that has a new and improved configuration and that enables holding down the impact of the stray light, which is generated at the lenses 60, on the wavelength detecting unit 30.

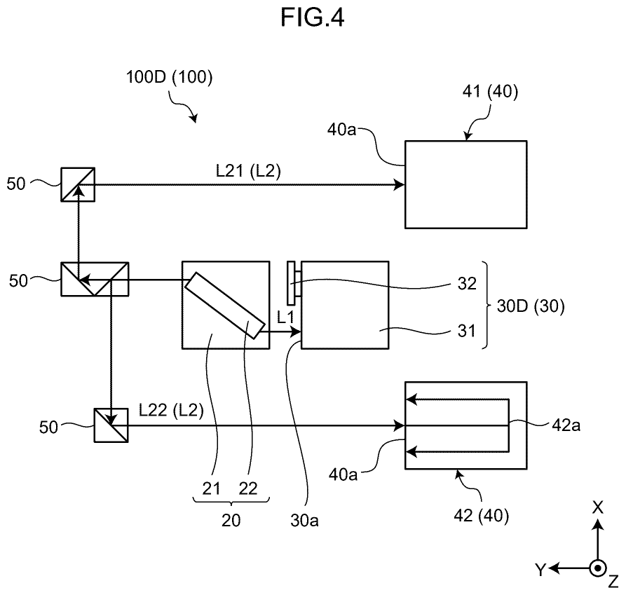

FIG. 4 is a planar view of an optical module 100D (100) according to a fourth embodiment. In FIG. 4, the housing 10 is not illustrated.

As illustrated in FIG. 4, the optical module 100D (100) according to the fourth embodiment has an identical configuration to the configuration according to the second embodiment. Hence, according to the fourth embodiment too, it is possible to achieve identical effects to the effects achieved according to the second embodiment.

However, in the fourth embodiment, as illustrated in FIG. 4, in a wavelength detecting unit 30D (30), with respect to the first portion 31, the second portion 32 is positioned on the opposite side of the incident surface 40a of each optical device 40. As a result, the stray light that is generated at the incident surface 40a does not easily reach the second portion 32 that includes the intensity detecting unit.

Hence, according to the fourth embodiment, for example, it becomes possible to obtain the optical module 100D (100) that has a new and improved configuration and that enables holding down the impact of the stray light, which is generated at the incident surface 40a, on the wavelength detecting unit 30.

Meanwhile, the wavelength detecting unit 30D according to the fourth embodiment may be substituted with the wavelength detecting unit 30A according to any of the other embodiments.

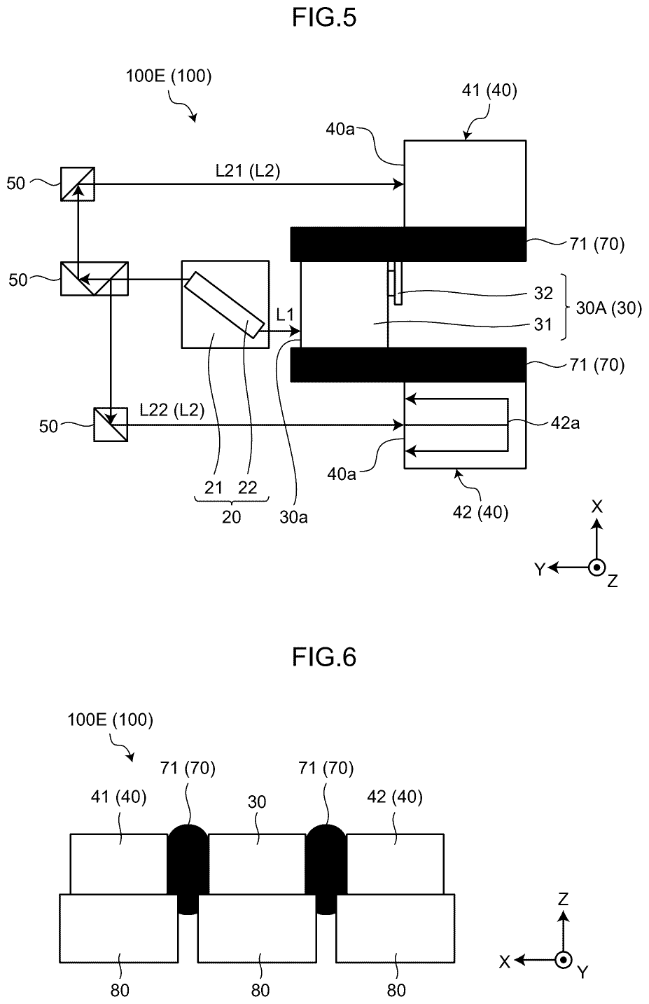

FIG. 5 is a planar view of an optical module 100E (100) according to a fifth embodiment. FIG. 6 is a front view of some portion of the optical module 100E (100) according to the fifth embodiment. In FIG. 5, the housing 10 is not illustrated.

As illustrated in FIG. 5, the optical module 100E (100) according to the fifth embodiment has an identical configuration to the configuration according to the second embodiment. Hence, according to the fifth embodiment too, it is possible to achieve identical effects to the effects achieved according to the second embodiment.

Moreover, in the fifth embodiment, as illustrated in FIGS. 5 and 6, a light absorbing member 71 that serves as a light blocking unit 70 is disposed in between the wavelength detecting unit 30 and the coherent mixer 41 serving as the optical device 40, as well as is disposed in between the wavelength detecting unit 30 and the modulator 42 serving as the optical device 40. Each light absorbing member 71 has a substantially constant width in the X direction, has a substantially constant height in the Z direction, and extends in the Y direction in between the end portion of the wavelength detecting unit 30 in the Y direction and the end portion of the corresponding optical device 40 in the opposite direction of the Y direction. The light absorbing members 71 are made of, for example, a black resin material having the property of absorbing the light. Each light absorbing member 71 functions as the light blocking unit 70 that blocks the stray light, which is generated in the corresponding optical device 40, from traveling toward the wavelength detecting unit 30. Moreover, since the light gets absorbed in the light absorbing members 71, it becomes possible to hold down the situation in which the stray light reflects from the light blocking units 70 or other portions and reaches the incident surface 30a. As illustrated in FIG. 6, the wavelength detecting unit 30, the coherent mixer 41, and the modulator 42 are supported by the bottom wall of the housing 10 (not illustrated) via supporting members 80. The supporting members 80 may be temperature regulation devices such as thermoelectric coolers (TECs).

According to the fifth embodiment, for example, it becomes possible to obtain the optical module 100E (100) that has a new and improved configuration and that enables further holding down the impact of the stray light, which is generated in the optical devices 40, on the wavelength detecting unit 30.

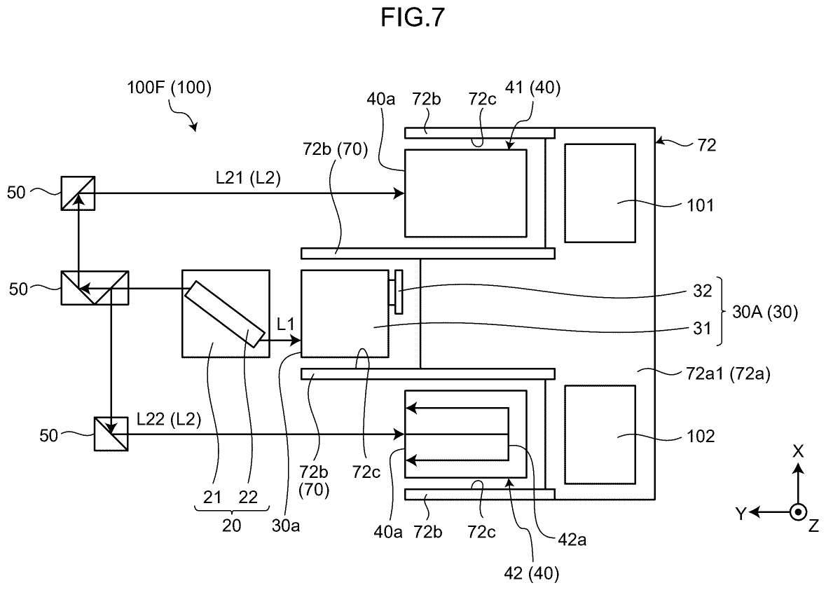

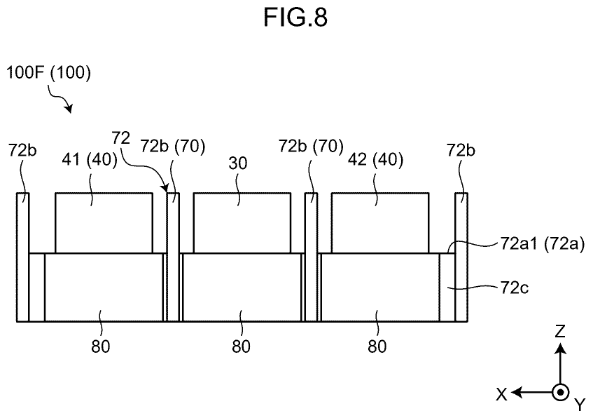

FIG. 7 is a planar view of an optical module 100F (100) according to a sixth embodiment. FIG. 8 is a front view of some portion of the optical module 100F (100) according to the sixth embodiment. In FIG. 7, the housing 10 is not illustrated.

As illustrated in FIG. 7, the optical module 100F (100) according to the sixth embodiment has an identical configuration to the configuration according to the second embodiment. Hence, according to the sixth embodiment too, it is possible to achieve identical effects to the effects achieved according to the second embodiment.

As illustrated in FIGS. 7 and 8, in the sixth embodiment too, in an identical manner to the fifth embodiment, the light blocking unit 70 is disposed in between the wavelength detecting unit 30 and the coherent mixer 41 serving as the optical device 40, as well as is disposed in between the wavelength detecting unit 30 and the modulator 42 serving as the optical device 40.

However, in the sixth embodiment, the light blocking units 70 are made of some part of a ceramic feed-through 72. The ceramic feed-through 72 passes through some portion of the peripheral wall of the housing 10 (see FIG. 2), and supports a transimpedance amplifier 101 and a modulator driver 102 inside the housing 10. The ceramic feed-through 72 includes the transimpedance amplifier 101, the modulator driver 102, and a wiring (not illustrated) that establishes electrical connection with a control device (not illustrated) disposed outside the housing 10. The ceramic feed-through 72 represents an example of a supporting member. Thus, the ceramic feed-through 72 may be said to constitute some part of the housing 10. Moreover, the ceramic feed-through 72 may also be referred to as a penetrating member, a mounting board, or a circuit board.

The transimpedance amplifier 101 converts the current signals, which are received from the coherent mixer 41, into voltage signals and outputs the voltage signals. The modulator driver 102 drives the modulator 42. The transimpedance amplifier 101 and the modulator driver 102 represent examples of an electronic component.

The ceramic feed-through 72 includes a substrate portion 72a and wall portions 72b. Moreover, notches 72c are formed in the ceramic feed-through 72.

The substrate portion 72a has a substantially constant thickness in the Z direction and expands while intersecting with the Z direction. A surface 72al that is present at the end portion of the substrate portion 72a in the Z direction faces in the Z direction and expands while intersecting with the Z direction. The transimpedance amplifier 101 and the modulator driver 102 are supported on the surface 72al. The surface 72al may also be referred to as a mounting surface.

Each wall portion 72b has a substantially constant width in the X direction, has a substantially constant height in the Z direction, and extends in the Y direction in between the end portion of the wavelength detecting unit 30 in the Y direction and the end portion of the corresponding optical device 40 in the opposite direction of the Y direction. The wall portions 72b protrude in the Z direction from the surface 72al of the substrate portion 72a.

When viewed from the opposite direction of the Z direction, each notch 72c is formed by making a cutout in such a way that the end portion in the Y direction is recessed in the opposite direction of the Y direction. In the ceramic feed-through 72, three notches 72c are provided. In each notch 72c, one of the wavelength detecting unit 30, the coherent mixer 41, and the modulator 42 is housed. The notches 72c may also be referred to as openings.

With such a configuration, the wall portions 72b function as the light blocking units 70 that block the light, which is received from the optical device 40, from traveling toward the incident surface 30a of the wavelength detecting unit 30. In each wall portion 72b, a light absorbing layer may be provided at least on the surface that faces the optical device 40. The light absorbing layer may be made of, for example, a black paint having light absorbing properties.

According to the sixth embodiment, for example, it becomes possible to obtain the optical module 100F (100) that has a new and improved configuration and that enables further holding down the impact of the stray light, which is generated in the optical devices 40, on the wavelength detecting unit 30.

Meanwhile, in the sixth embodiment, the position of the surface 72al in the Z direction is same as the positions of the end faces of the optical devices 40 in the opposite direction of the Z direction (i.e., the bottom surfaces of the optical devices 40). However, that is not the only possible case. For example, the position of the surface 72a1 in the Z direction either may be same as the positions of the end faces of the optical devices 40 in the Z direction (i.e., the top surfaces of the optical devices 40), or may be in between the bottom surfaces and the top surfaces of the optical devices 40.

While certain embodiments and modification examples have been described, these embodiments and modification examples have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. Moreover, regarding the constituent elements, the specifications about the configurations and the shapes (structure, type, direction, shape, size, length, width, thickness, height, number, arrangement, position, material, etc.) may be suitably modified.

For example, the present disclosure may be also implemented in an optical module that includes an optical device other than a coherent mixer or a modulator. Moreover, the layout of the light emitting device, the wavelength detecting unit, and the optical device may also be varied in various ways.

According to the present disclosure, for example, it becomes possible to obtain an optical module having a new and improved configuration.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical module comprising:
a housing;
a light emitting device housed in the housing;
a wavelength detecting unit configured to detect wavelength of a first light which is output in a first direction from the light emitting device housed in the housing; and
an optical device housed in the housing and configured to receive input of a second light traveling substantially parallel to the first light, wherein
a first incident surface of the wavelength detecting unit, on which the first light falls, is positioned away from a second incident surface of the optical device, on which the second light falls, in an opposite direction of the first direction.

2. The optical module according to claim 1, wherein light output from the light emitting device in the opposite direction of the first direction passes through a first optical component, and is then input as the second light to the optical device.

3. The optical module according to claim 1, wherein
the optical device includes a folded portion within which light is turned back in the opposite direction of the first direction, and
the first incident surface is positioned away from the folded portion in the opposite direction of the first direction.

4. The optical module according to claim 1, further comprising a second optical component facing in the opposite direction of the first direction with respect to the second incident surface and through which passes the second light before falling on the second incident surface, wherein
the first incident surface is positioned away from the second optical component in the opposite direction of the first direction.

5. The optical module according to claim 1, wherein
the wavelength detecting unit includes
a first portion including an optical filter, the first portion being configured to receive input of the first light, and
a second portion including an intensity detecting unit configured to detect intensity of light that has passed through the first portion, and
the second portion is positioned on an opposite side of the second incident surface with respect to the first portion.

6. The optical module according to claim 1, further comprising a light blocking unit disposed between the wavelength detecting unit and the optical device.

7. The optical module according to claim 6, wherein the light blocking unit includes a light absorbing member configured to absorb light.

8. The optical module according to claim 6, wherein the light blocking unit is a part of a supporting member configured to support an electronic component.

9. The optical module according to claim 1, wherein the optical device is a coherent mixer.

10. The optical module according to claim 1, wherein the optical device is a modulator.
